(19) United States
(12) Patent Application Publication
(10) Pub. No.: US 2026/0059714 A1
(43) Pub. Date: Feb. 26, 2026

(54) APPARATUS USING LINKAGE FOR COUPLING A HEATSINK TO A CAGE

(71) Applicants: FOXCONN (KUNSHAN) COMPUTER CONNETOR CO., LTD., Kunshan (CN); FOXCONN INTERCONNECT TECHNOLOGY LIMITED, Grand Cayman (KY)

(72) Inventors: CHANG-MING YANG, Irvine, CA (US); TERRANCE F. LITTLE, Fullerton, CA (US)

(21) Appl. No.: 19/299,685

(22) Filed: Aug. 14, 2025

Related U.S. Application Data
(60) Provisional application No. 63/686,118, filed on Aug. 22, 2024.

(51) Int. Cl. H05K 7/20

(52) U.S. Cl. CPC H05K 7/20409

(57) ABSTRACT

An apparatus includes: a cage having a front opening and an upper opening at an upper wall thereof; a heatsink including a front portion movably supported at a front of the cage, a rear portion movably retained at a rear of the cage, and a bottom portion near the upper opening of the cage; a spring holding the front portion of the heatsink; and a linkage deployable by a module inserted into the cage through the front opening to move the heatsink from an open state where the bottom portion is tilted relative to the upper wall to a closed state where the bottom portion enters the cage through the upper opening.

### CROSS REFERENCE TO RELATED APPLICATION

This application claims priority to and benefit of U.S. Provisional Patent Application No. 63/686118, filed Aug. 22, 2024.

### BACKGROUND OF THE INVENTION

### Field of the Invention

The present invention relates to an apparatus comprising a cage, a heatsink to be mounted to the cage, and means for actuating the heatsink to mount to the cage for dissipating heat from a module inserted into the cage.

### Description of Related Arts

U.S. Pat. No. 11,700,712 discloses a cage assembly for receiving an electronic component, comprising a cage, a floating heatsink (in contrast to a riding heatsink), a pivoted lever arm, and an actuator deployable by insertion of the electronic component to pivot the lever arm for lowering the heatsink to contact the electronic component.

U.S. Pat. No. 10,212,852 discloses an apparatus comprising a heatsink having at least one stopper pin at a rear thereof and plural guide pins at sides thereof, a cage having plural sliding profile ramps for receiving corresponding guide pins, and a spring coupled to a back side of the cage. In use, an inserted field-replaceable electronic module pushes the stopper pin of the heatsink to move the heatsink downwardly by way of the guide pins and the ramps in order for the heatsink to press on the module against a force of the spring. In a varied design, the guide pins, instead of being provided on the heatsink, may be disposed on a separate spring plate that is coupled and applies force to the heatsink.

### SUMMARY OF THE INVENTION

An apparatus comprises: a cage having a front opening and an upper opening at an upper wall thereof; a heatsink including a front portion movably supported at a front of the cage, a rear portion movably retained at a rear of the cage, and a bottom portion near the upper opening of the cage; a spring holding the front portion of the heatsink; and a linkage deployable by a module inserted into the cage through the front opening to move the heatsink from an open state where the bottom portion is tilted relative to the upper wall to a closed state where the bottom portion enters the cage through the upper opening.

### BRIEF DESCRIPTION OF DRAWINGS

FIG. 1 is a perspective view of an apparatus in accordance with the present invention;

FIG. 2 is a perspective view showing a cage of the apparatus being separated from the other components of the apparatus;

FIG. 3 is a perspective view of the other components in FIG. 2;

FIG. 4 is an exploded view of the apparatus omitting the cage;

FIG. 5 is a view similar to FIG. 4 but from another perspective;

FIG. 6 is an assembled side view showing a linkage, a spring, and a heatsink of the apparatus at an open state;

FIG. 7 is a view showing the linkage, the spring, and the heatsink at a closed state;

FIG. 8 is a perspective view of a frame of the apparatus;

FIG. 9 is a view similar to FIG. 8 but from another perspective;

FIG. 10 is a perspective view of the linkage;

FIG. 11 is a view similar to FIG. 10 but from another perspective;

FIG. 12 is an exploded view of the linkage;

FIG. 13 is a perspective view of the spring;

FIG. 14 is a view similar to FIG. 13 but from another perspective;

FIG. 15 is a perspective view of the heatsink;

FIG. 16 is a view similar to FIG. 15 but from another perspective;

FIG. 17 is a view similar to FIG. 4 but showing a varied design;

FIG. 18 is a view similar to FIG. 17 but from another perspective;

FIG. 19 is an assembled side view showing the varied design at an open state;

FIG. 20 is a view showing the varied design at a closed state;

FIG. 21 is a perspective view of a varied frame;

FIG. 22 is a view similar to FIG. 21 but from another perspective;

FIG. 23 is a perspective view of a varied linkage;

FIG. 24 is a view similar to FIG. 23 but from another perspective;

FIG. 25 is a perspective view of a varied heatsink; and

FIG. 26 is a view similar to FIG. 25 but from another perspective.

### DETAILED DESCRIPTION OF THE DRAWINGS

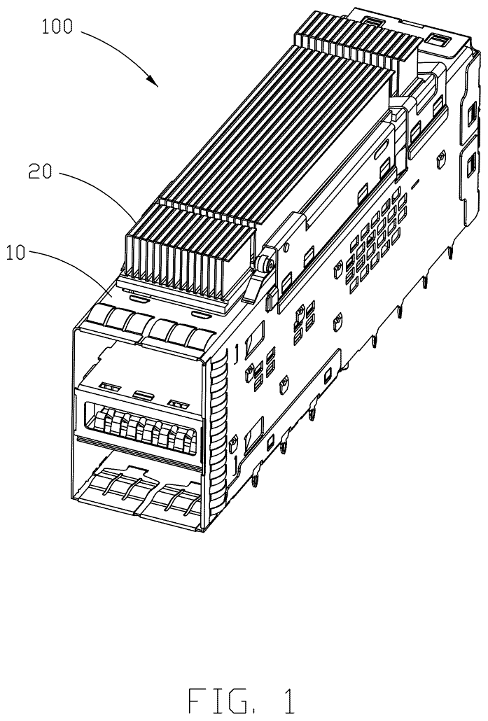

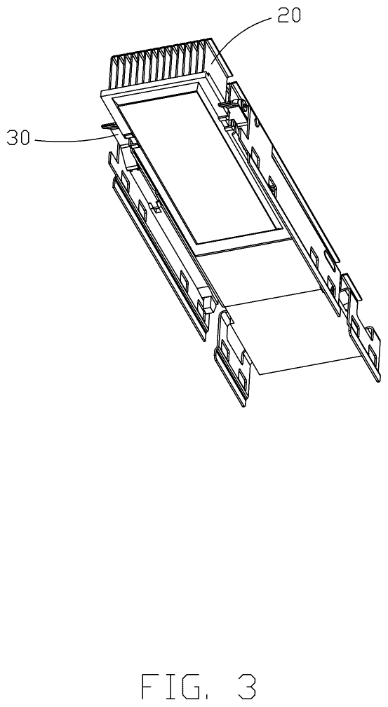

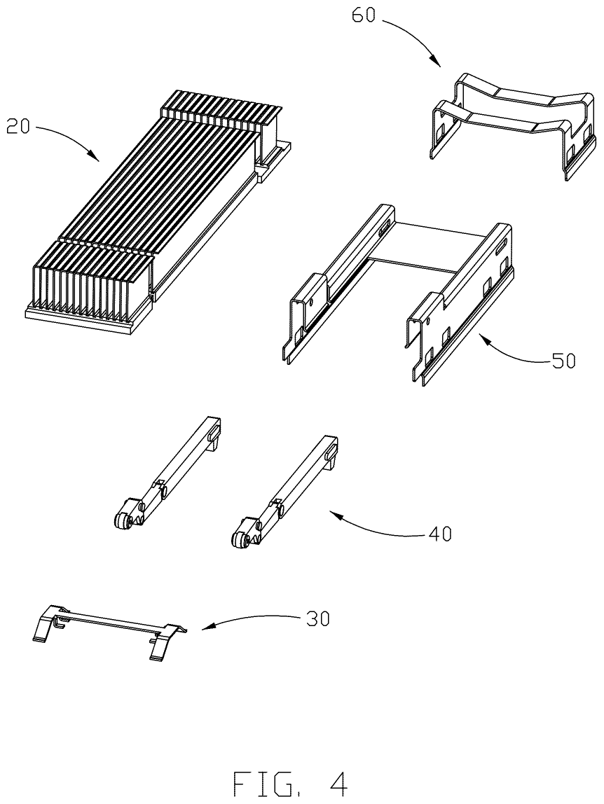

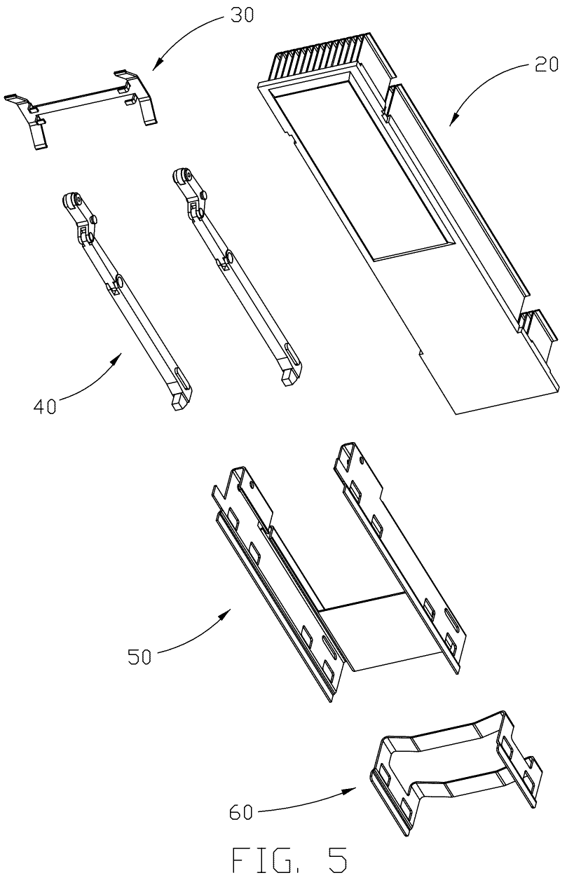

Referring to FIGS. 1-7, an apparatus 100 comprises a cage 10 having a front opening 12 and an upper opening 14 at an upper wall 16 thereof, a heatsink 20 mounted at the upper wall 16 of the cage 10, a spring 30 supporting one end of the heatsink 20, and a linkage 40 disposed beside the heatsink 20 and coupled to the spring 30. It is intended that at an open state where a pluggable module is not yet inserted into the cage 10, a front of the heatsink 20 is held and urged by the spring 30 so that the heatsink 20 is tilted. At a closed state, when the pluggable module is inserted and therefore operates on the linkage 40, the linkage 40 in turn operates against the spring 30 to move the heatsink 20 from the tilted position to a horizontal position where a bottom of the heatsink 20 engages a top of the inserted module for heat dissipation purpose. The change of positions or orientations from tilted to horizontal is desired especially when a thermal interface material (“TIM”) is provided on a bottom surface of the heatsink 20 to improve thermal conductivity. Since the TIM is fragile it is better for the TIM to not be in direct contact with a moving module during its insertion into the cage.

The apparatus may further include a separate frame 50 and an additional clip 60. Otherwise, the cage 10 may have integral structures or features to suitably retain the heatsink 20 and/or other integral structures or features to properly contain the linkage 40. Respective structures of the components 10, 20, 30, and 40 as well as the components 50 and 60, if present, and their positional and operational relationships will be detailed later.

The cage 10 is generally of a known structure which in this embodiment is shown as a stacked type with upper and lower ports for insertion of upper and lower pluggable modules, respectively. The cage may be constructed to have a single port only or one or more rows of ports. A corresponding receptacle connector is disposed inside the cage 10 for interconnecting with inserted module or modules. Also well known in this art is that pluggable modules may have latch features, e.g., latching pockets and a latch release mechanism at both sides thereof and cages may have corresponding features disposed on both sides thereof to latch the module into the cage. Moreover, cage forward stop and module forward stop may be designed to determine a forward inserted position of the module into the cage in a well known manner.

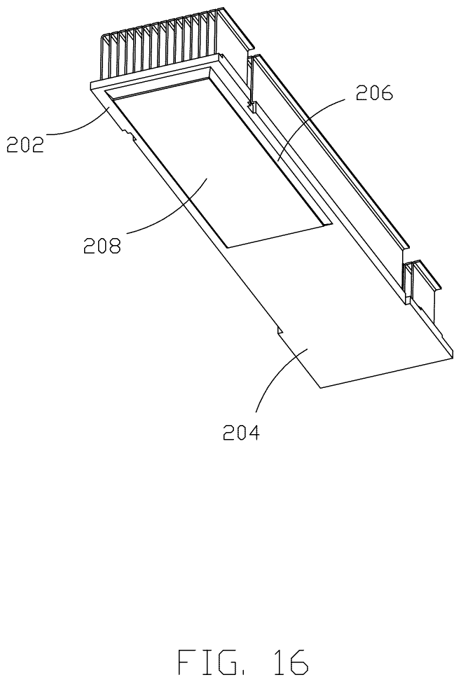

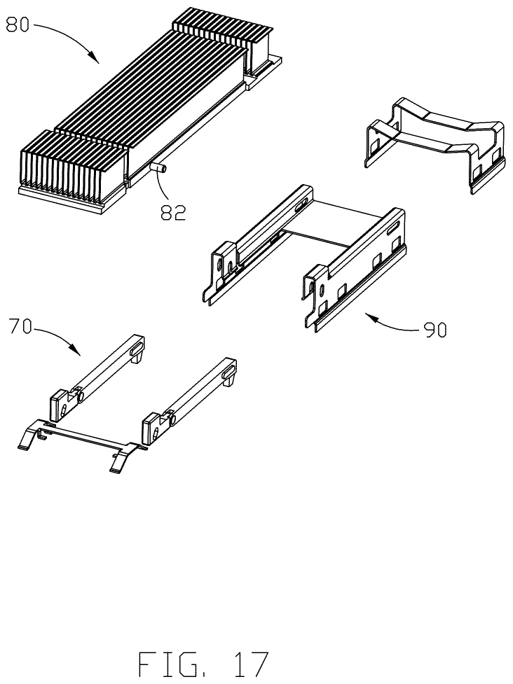

As shown in FIGS. 15 and 16, the heatsink 20 has a front portion 202 to be movably supported at a front of the cage 10 by way of the spring 30, a rear portion 204 movably retained at a rear of the cage 10, e.g., by way of the clip 60, and a bottom portion 206 located near the upper opening 14 of the cage 10. The bottom portion 106 of the heatsink 20 may have a TIM interface 208. The heatsink 20 may have a plurality of fins 22. A first groove 24 may be formed at the front portion 202 and be straddled by the spring 30; a second groove 26 may be formed at the rear portion 204 and be straddled by the clip 60.

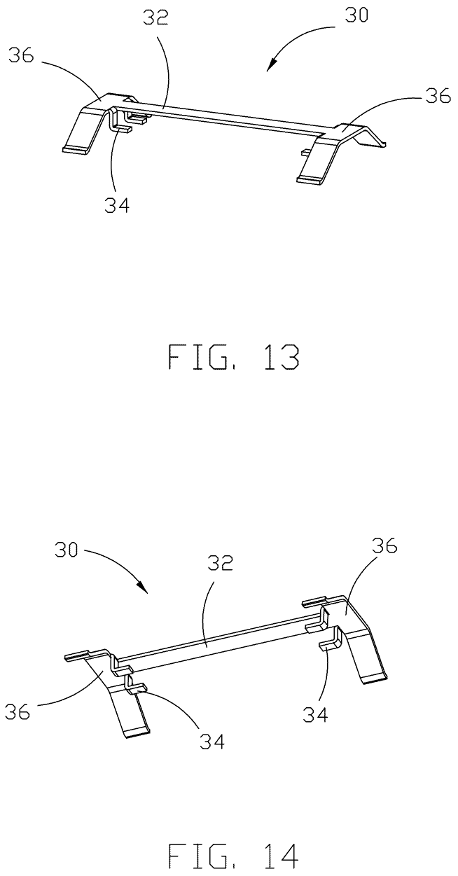

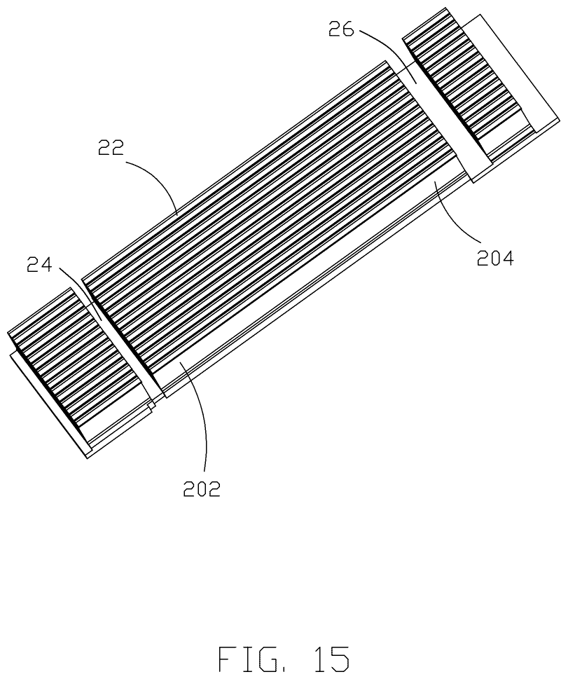

As shown in FIGS. 13 and 14, the spring 30 has an upper portion 32, a lower portion 34, and a spring plate 36. The spring plate 36 may be in the form of a pair of spring portions connected at two ends of the upper portion 32. The lower portion 34 may be in the form of one or more fingers connected at each of the pair of the spring plate 36. The upper portion 32 is received in the first groove 24 of the heatsink 20 and the lower portion 34 extends under the heatsink 20. The upper portion 32 and the lower portion 34 are designed to clamp the heatsink 20. The spring plate 36 is pressed between the linkage 40 and the cage 10. The spring plate 36 provides an upward resilient force on the lower portion 34, which in turn pushes the heat sink 20 upward. When the spring plate 36 is pressed downward by the linkage 40 against the cage 10, the upper and lower portions 32 and 34 will move the heatsink 20 downward.

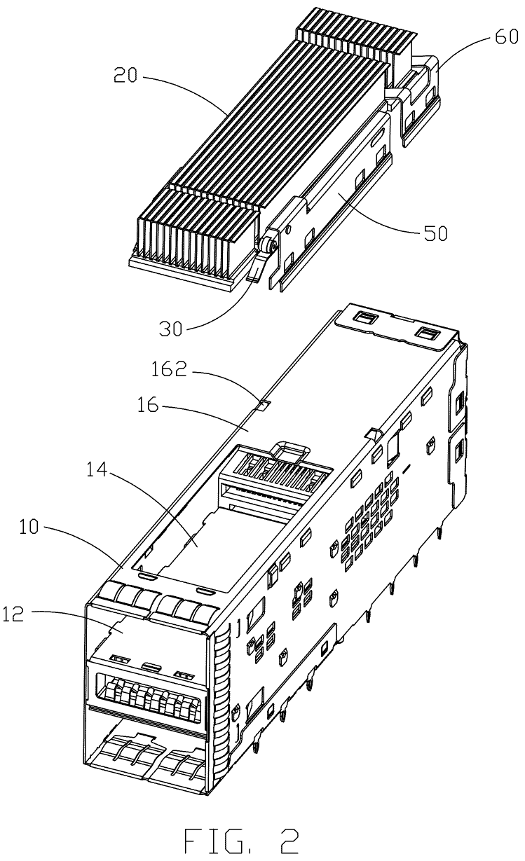

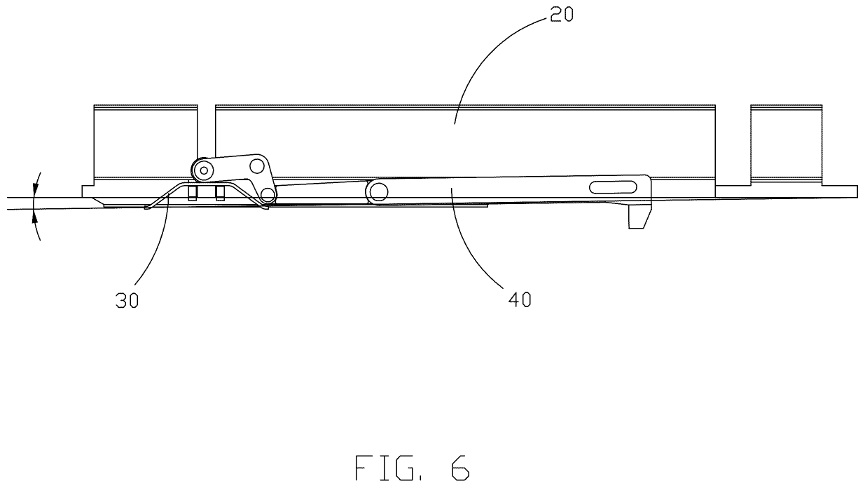

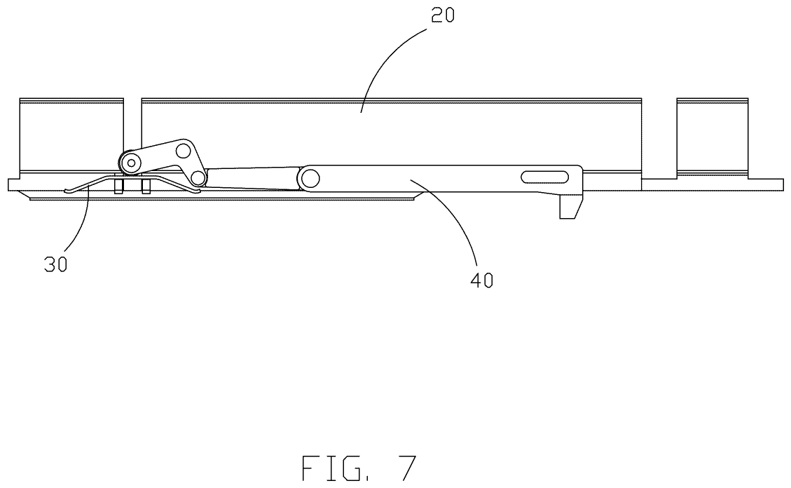

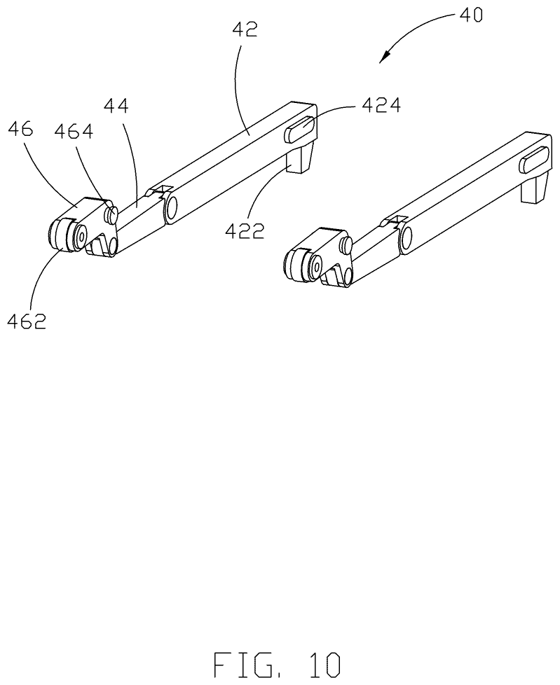

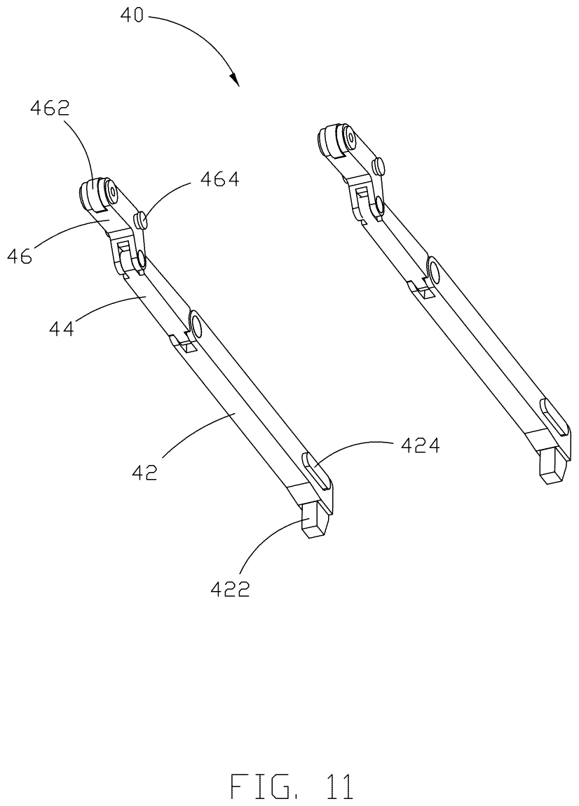

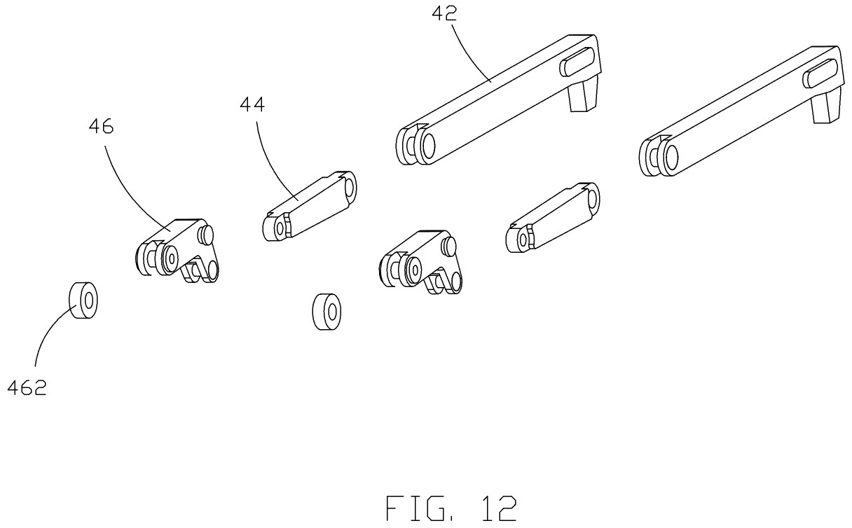

As shown in FIGS. 10-12, the linkage 40 may be in the form of a pair of linkage portions disposed at two opposite sides of the heatsink 20. Each linkage portion may include an actuating link 42, a connecting link 44 pivotably connected to the actuating link 42, and a front lever 46 pivotably connected to the connecting link 44 for exerting a downward force to the spring 30 and the heatsink 20. The actuating link 42 has a leg 422 extending into the cage 10 through a hole 162 (FIG. 2) thereof to be operated by a pluggable module during its insertion. The actuating link 42 may further have a pair of guides 424 to be mounted to the frame 50. The lever 46 includes a roller 462 for a smooth movement on the spring plate 36 of the spring 30. The lever 46 has a pivot 464, e.g., a pair of pivot portions on opposite sides thereof, to be also mounted to the frame 50. Therefore, the linkage 40 is deployable by a module inserted into the cage 10 through the front opening 12, and when deployed the actuating link 42 moves the connecting link 44 in a direction away from the front lever 46, and the connecting link 44 in turn moves the lever 46 toward the actuating link 42 to effectuate a pivoting movement of the lever 46 about the pivot 464. The pivoting movement of the lever 46 results in a downward and rearward movement of the roller 462 in addition to its rolling movement. The lever 46 then moves the heatsink 20 from an open state shown in FIG. 6 where the bottom portion 206 is tilted, e.g., one (1) degree, relative to the upper wall 16 to a closed state shown in FIG. 7 where the bottom portion is horizontal and enters the cage 10 through the upper opening 14. It is contemplated that the linkage 40 may be suitably supported by the cage 10 without needing the frame 50, e.g., the cage 10 may have a feature or like structure to support the pivot 464.

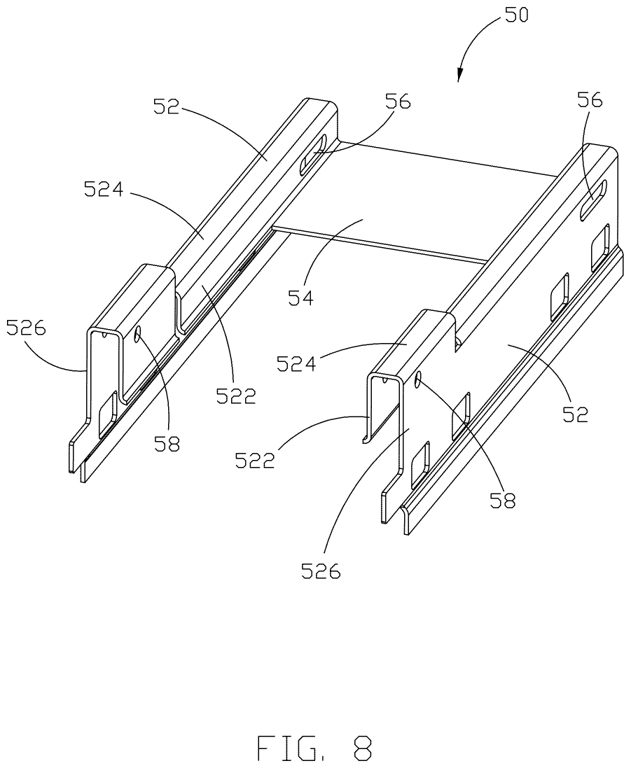

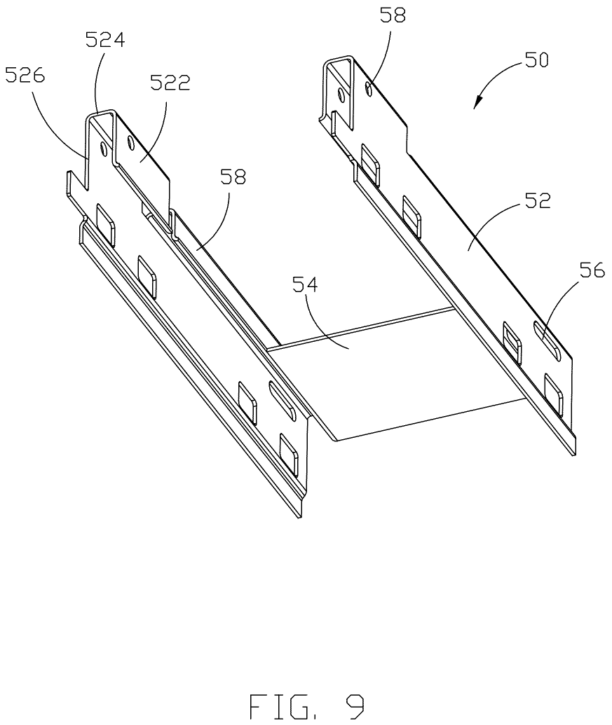

The frame 50 is to be attached to the cage 10 for guiding a movement of the linkage 40. As shown in FIGS. 8 and 9, the frame 50 may include a pair of frame portions 52 corresponding to the pair of linkage portions of the linkage 40 and a connecting portion 54 between the pair of frame portions 52. Each frame portion 52 has an inner wall 522, an upper wall 524, and an outer wall 526. The inner wall 522 and/or the connecting portion 54 may be supported on the upper wall 16 of the cage 10. The outer wall 526 may be fastened to a side wall of the cage 10, e.g., through tabs and holes engagement. A groove 56 is formed on the frame 50 and may extend through the inner and outer walls 522 and 526. A hole 58 is formed on the frame 50 and may also extend through the inner and outer walls 522 and 526. The groove 56 receives the pair of guides 424 to guide a translational movement of the actuating link 42. The hole 58 receives the pivot 464 or the pair of pivot portions to effectuate a pivotal movement of the lever 46.

The clip 60 is provided to retain the rear portion of the heatsink 20 to the rear of the cage 10. It is contemplated that the cage 10 may have a suitable feature or like structure to movably retain the rear portion of the heatsink 20 at the rear of the cage 10. It is noted that the clip 60 retained the rear portion of the heatsink 20 at the rear of the cage 10 such that a controlled tilting movement of the front of the heatsink 20 relative to the cage 10 by way of the linkage 40 may be achieved.

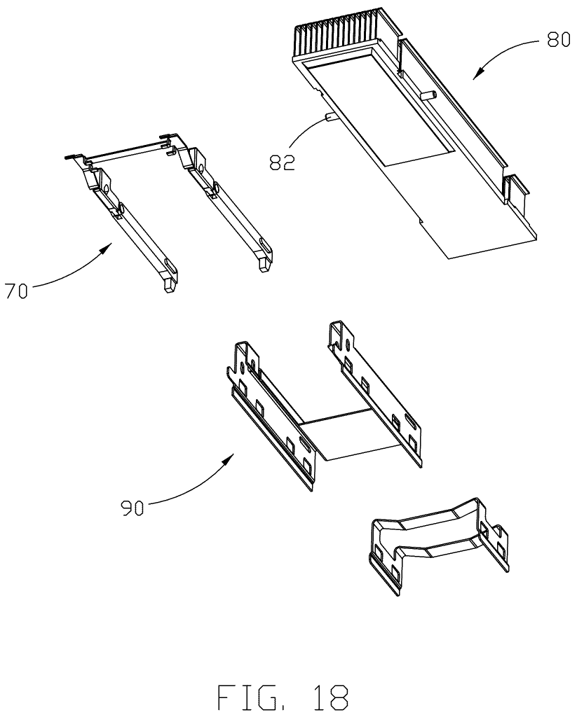

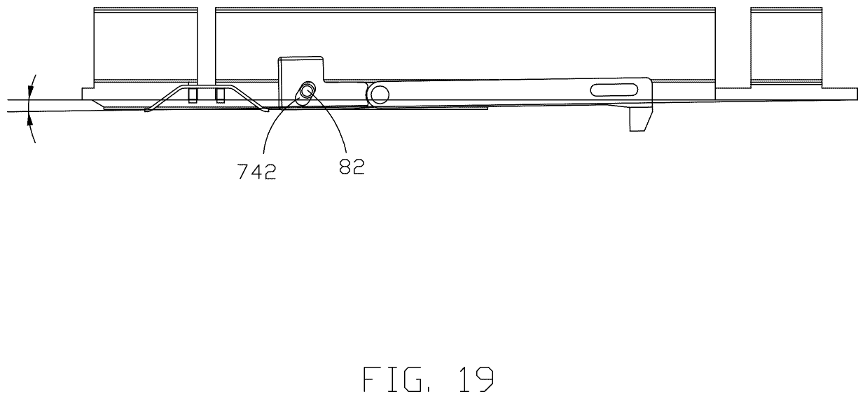

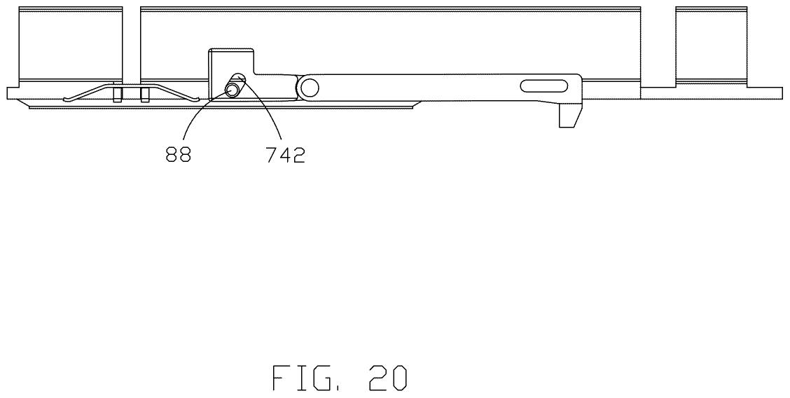

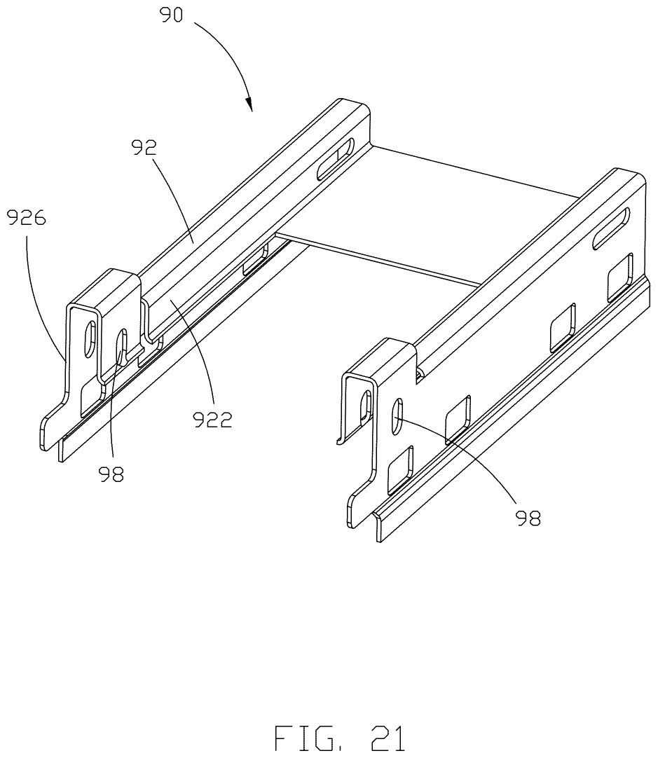

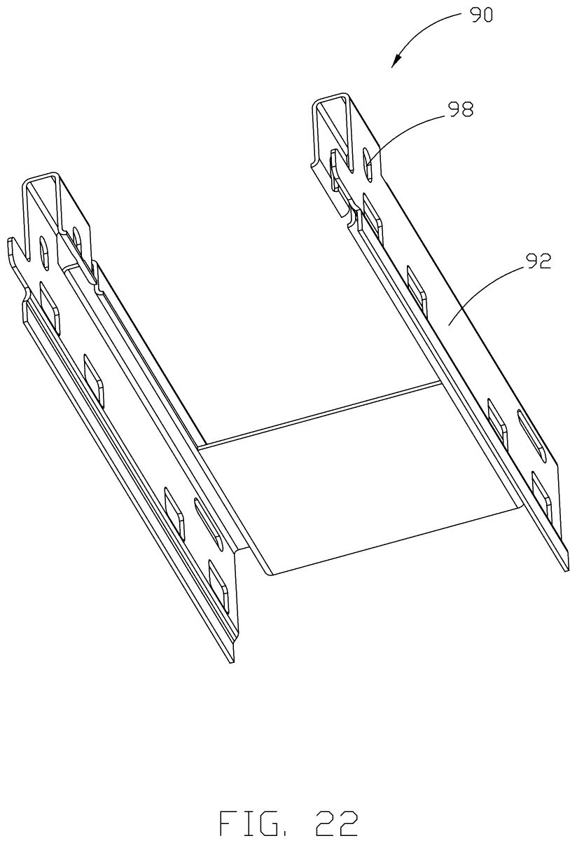

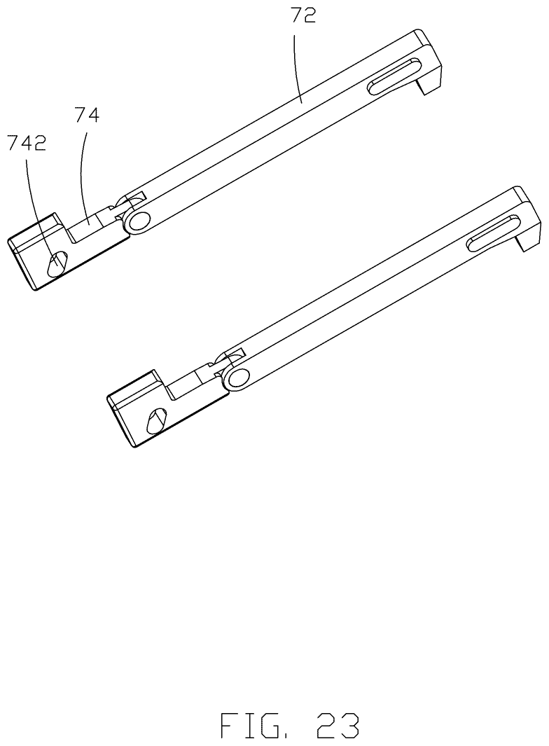

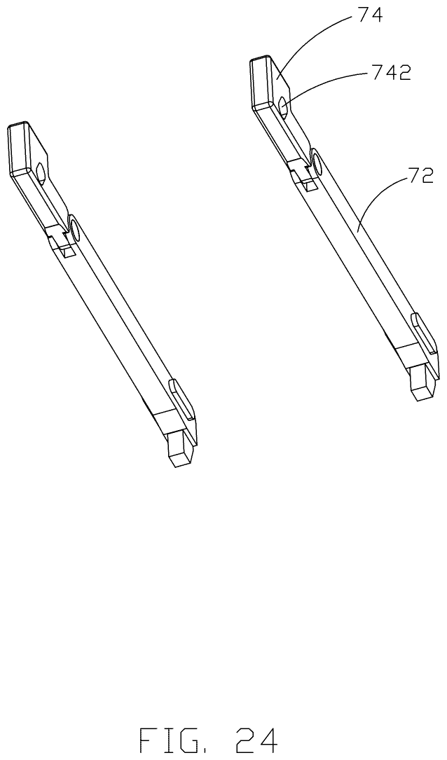

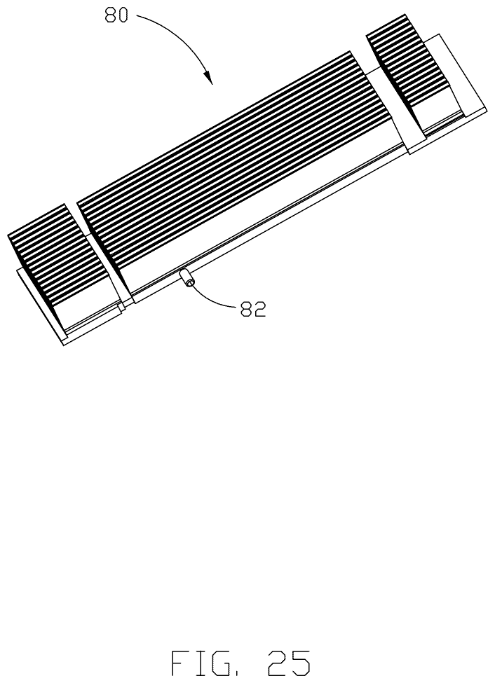

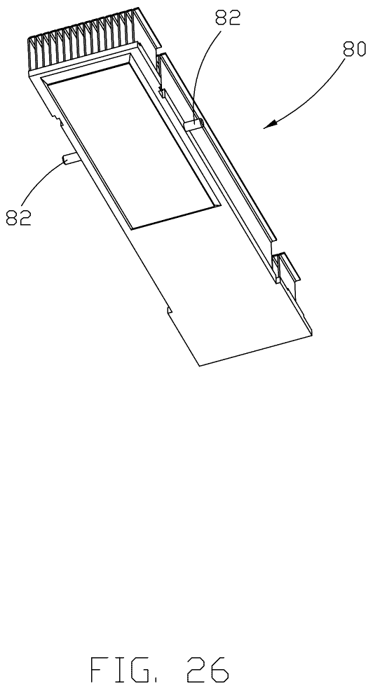

Referring to FIGS. 17-26, a varied design of apparatus 100 features a linkage 70 and a corresponding heatsink 80 and a frame 90; other components shown may be substantially similar as those correspondingly shown in FIGS. 1-16 so that a description thereof is omitted. Specifically, the linkage 70 may be in the form of a pair of linkage portions disposed at two opposite sides of the heatsink 80. Each linkage portion may include an actuating link 72 and a front slider 74 pivotably connected to the actuating link 72. The slider 74 has a hole 742. The heatsink 80 may have a pair of pins 82 each received in a corresponding hole 742. The hole 742 is designed, e.g., elongated and slanted, so that a horizontal movement of the slider 74 is translated into an up and down movement of the heatsink 80 by way of the pin 82. For example, at the open state of FIG. 19, the pin 82 is positioned at upper-right of the hole 742 while at the closed state of FIG. 20, the pin 82 is positioned at lower-left of the hole 742. In this varied design, the linkage 70 is not required to be coupled to the corresponding spring.

The frame 90 may have an elongate hole 98 extending through an inner wall 922 and an outer wall 926 thereof. The elongate hole 98 is adapted to the up and down movement of the heatsink 80 through the pin 82.

1. An apparatus comprising:
a cage having a front opening and an upper opening at an upper wall thereof;
a heatsink including a front portion movably supported at a front of the cage, a rear portion movably retained at a rear of the cage, and a bottom portion near the upper opening of the cage;
a spring holding the front portion of the heatsink; and
a linkage deployable by a module inserted into the cage through the front opening to move the heatsink from an open state where the bottom portion is tilted relative to the upper wall to a closed state where the bottom portion enters the cage through the upper opening.

2. The apparatus as claimed in claim 1, further comprising a frame attached to the cage for guiding a movement of the linkage.

3. The apparatus as claimed in claim 2, wherein the linkage comprises an actuating link, a connecting link pivotably connected to the actuating link, and a front lever pivotably connected to the connecting link for exerting a downward force to the heatsink.

4. The apparatus as claimed in claim 3, wherein the actuating link has a leg extending into the cage through a hole thereof to be operated by a pluggable module during insertion of the pluggable module.

5. The apparatus as claimed in claim 4, wherein the actuating link has a pair of guides to be mounted to the frame, and the front lever includes a roller for a smooth movement on the spring plate of the spring.

6. The apparatus as claimed in claim 5, wherein the front lever has a pivot on opposite sides thereof to be also mounted to the frame.

7. The apparatus as claimed in claim 6, wherein the linkage comprises a pair of linkage portions disposed at two opposite sides of the heatsink, and the frame comprises a pair of frame portions corresponding to the pair of linkage portions of the linkage and a connecting portion between the pair of frame portions.

8. The apparatus as claimed in claim 7, wherein each frame portion has an inner wall, an upper wall, and an outer wall, at least one of the inner wall and the connecting portion is supported on the upper wall of the cage, and the outer wall is fastened to a side wall of the cage.

9. The apparatus as claimed in claim 8, wherein the frame has a groove extending through the inner and outer walls, and a hole extending through the inner and outer walls, the groove receives the pair of guides to guide a translational movement of the actuating link, and the hole receives the pivot to effectuate a pivotal movement of the lever.

10. The apparatus as claimed in claim 1, wherein the linkage comprises an actuating link and a front slider pivotably connected to the actuating link, and the heatsink comprises a pin guided by the front slider for moving the heatsink.

11. The apparatus as claimed in claim 10, wherein the front slider has a hole for receiving the pin of the heatsink.

12. The apparatus as claimed in claim 11, wherein the hole is elongated and slanted so that a horizontal movement of the front slider is translated into an up and down movement of the heatsink by way of the pin.

13. The apparatus as claimed in claim 10, wherein the frame has an elongate hole extending through an inner wall and an outer wall thereof to adapt to the up and down movement of the heatsink through the pin.

14. The apparatus as claimed in claim 1, wherein the rear portion of the heatsink is movably retained at the rear of the cage by a clip.

15. The apparatus as claimed in claim 1, wherein:
the spring comprises an upper portion, a lower portion, and a spring plate;
the upper portion and the lower portion clamp the heatsink; and
the spring plate is pressed between the linkage and the cage.

16. The apparatus as claimed in claim 15, wherein a first groove is formed at the front portion and straddled by the spring; a second groove is formed at the rear portion and straddled by the clip.

17. The apparatus as claimed in claim 16, wherein the upper portion of the spring is received in the first groove of the heatsink and the lower portion of the spring extends under the heatsink.

18. The apparatus as claimed in claim 1, wherein the bottom portion of the heatsink comprises a TIM interface.

19. The apparatus as claimed in claim 1, wherein the heatsink comprises a plurality of fins.
